(19) United States
(12) Patent Application Publication
(10) Pub. No.: US 2024/0113245 A1
(43) Pub. Date: Apr. 4, 2024

(54) SEMICONDUCTOR PHOTODETECTOR

(71) Applicant: Sumitomo Electric Industries, Ltd., Osaka (JP)

(72) Inventor: Takashi KATO, Osaka-shi (JP)

(73) Assignee: Sumitomo Electric Industries, Ltd., Osaka (JP)

(21) Appl. No.: 18/242,662

(22) Filed: Sep. 6, 2023

(30) Foreign Application Priority Data
Sep. 30, 2022 (JP) 2022-157893

(51) Int. Cl. H01L 31/105; H01L 31/0304

(52) U.S. Cl. CPC H01L 31/105; H01L 31/03046

(57) ABSTRACT

A semiconductor photodetector includes an optical absorption layer. The optical absorption layer includes a plurality of unit structures stacked in a first direction, each of the plurality of unit structures includes a laminate and a gallium arsenide antimonide layer, the laminate includes a first gallium arsenide layer including j gallium arsenide monolayers, a first indium arsenide layer including m indium arsenide monolayers, k stacked structures, and a second gallium arsenide layer including (j−1) gallium arsenide monolayers, each of the k stacked structures includes a third gallium arsenide layer including n gallium arsenide monolayers, and a second indium arsenide layer including m indium arsenide monolayers, j, m, and n are each an integer of 1 or more, and k is an integer of 0 or more.

### CROSS REFERENCE TO RELATED APPLICATIONS

This application claims priority based on Japanese Patent Application No. 2022-157893 filed on Sep. 30, 2022, and the entire contents of the Japanese patent application are incorporated herein by reference.

### TECHNICAL FIELD

The present disclosure relates to a semiconductor photodetector.

### BACKGROUND

Rubin Sidhu, et al, “A Long-Wavelength Photodiode on InP Using Lattice-Matched GaInAs—GaAsSb Type-II Quantum Wells” IEEE PHOTONICS TECHNOLOGY LETTERS, VOL. 17, NO. 12, DECEMBER 2005, p. 2715-2717, referred to as Non-patent document 1, discloses a photodiode comprising an optical absorption layer disposed on an n-type indium phosphide (InP) substrate. The optical absorption layer has 150 pairs of type-II superlattices. One pair includes a gallium indium arsenide (GaInAs) layer and a gallium arsenide antimonide (GaAs Sb) layer.

### SUMMARY

A semiconductor photodetector according to an aspect of the present disclosure includes a first group III-V semiconductor layer of a first conductivity type, a second group III-V semiconductor layer of a second conductivity type, and an optical absorption layer disposed between the first group III-V semiconductor layer and the second group III-V semiconductor layer in a first direction. The optical absorption layer includes a plurality of unit structures stacked in the first direction; each of the plurality of unit structures includes a laminate and a gallium arsenide antimonide layer; the laminate includes a first gallium arsenide layer including j gallium arsenide monolayers, a first indium arsenide layer including m indium arsenide monolayers, k stacked structures, and a second gallium arsenide layer including (j−1) gallium arsenide monolayers, the second gallium arsenide layer, the k stacked structures, the first indium arsenide layer, and the first gallium arsenide layer are stacked in this order in the first direction, each of the k stacked structures includes a third gallium arsenide layer including n gallium arsenide monolayers and a second indium arsenide layer including m indium arsenide monolayers, and in each of the k stacked structures, the second indium arsenide layer and the third gallium arsenide layer are stacked in this order in the first direction; and j, m, and n are each an integer of 1 or more, and k is an integer of 0 or more.

### BRIEF DESCRIPTION OF THE DRAWINGS

FIG. 1 schematically shows a cross-sectional view of a semiconductor photodetector according to an embodiment.

FIG. 2 is a cross-sectional view schematically showing an optical absorption layer included in the semiconductor photodetector of FIG. 1.

FIG. 3 is a cross-sectional view schematically showing a unit structure included in the optical absorption layer of FIG. 2.

FIG. 4 is a graph showing an example of an energy band diagram in an optical absorption layer of a semiconductor photodetector according to a first experiment.

FIG. 5 is a graph showing an example of an energy band diagram in an optical absorption layer of a semiconductor photodetector according to a second experiment.

FIG. 6 is a graph showing an example of a spectrum of an optical-absorption coefficient obtained in a first experiment.

FIG. 7 is a graph showing an example of a spectrum of an optical-absorption coefficient obtained in a second experiment.

FIG. 8 is a perspective view showing an example of an atomic arrangement in a unit structure of a first experiment.

FIG. 9 is a perspective view showing an example of an atomic arrangement in a unit structure of a first experiment.

FIG. 10 is a perspective view showing an example of an atomic arrangement in a unit structure of a second experiment.

FIG. 11 is a perspective view showing an example of an atomic arrangement in a unit structure of a second experiment.

FIG. 12 shows examples of wavelengths of the optical absorption edge in the unit structures of a first experiment, a third experiment to a 25th experiment.

### DETAILED DESCRIPTION

In the photodiode of Non-patent document 1, a spectrum of an optical-absorption coefficient greatly changes according to a polarization direction of incident light.

The present disclosure provides a semiconductor photodetector with a spectrum of an optical-absorption coefficient having a little dependence on a polarization direction of incident light.

[Description of Embodiments of Present Disclosure]

First, embodiments of the present disclosure will be listed and described.

(1) A semiconductor photodetector includes a first group III-V semiconductor layer of a first conductivity type, a second group III-V semiconductor layer of a second conductivity type, and an optical absorption layer disposed between the first group III-V semiconductor layer and the second group III-V semiconductor layer in a first direction. The optical absorption layer includes a plurality of unit structures stacked in the first direction, each of the plurality of unit structures includes a laminate and a gallium arsenide antimonide layer, the laminate includes a first gallium arsenide layer including j gallium arsenide monolayers, a first indium arsenide layer including m indium arsenide monolayers, k stacked structures, and a second gallium arsenide layer including (j−1) gallium arsenide monolayers, the second gallium arsenide layer, the k stacked structures, the first indium arsenide layer, and the first gallium arsenide layer are stacked in this order in the first direction, each of the k stacked structures includes a third gallium arsenide layer including n gallium arsenide monolayers and a second indium arsenide layer including m indium arsenide monolayers, and in each of the k stacked structures, the second indium arsenide layer and the third gallium arsenide layer are stacked in this order in the first direction, and j, m, and n are each an integer of 1 or more, and k is an integer of 0 or more.

According to the semiconductor photodetector, the laminate in each unit structure functions as an electron well layer. In the semiconductor photodetector, a spectrum of an optical-absorption coefficient has lower dependence on a polarization direction of incident light than in a case where the electron well layer in each unit structure is formed of only a GaInAs layer. This is considered to be because an atomic arrangement has symmetry with respect to a center position of the electron well layer in the first direction.

(2) In the above (1), the semiconductor photodetector may further includes an indium phosphide substrate. The first group III-V semiconductor layer may be disposed between the indium phosphide substrate and the optical absorption layer in the first direction, and 0.95<y+r<1.05 may be satisfied, where y is an arsenic fraction in the gallium arsenide antimonide layer, and r is a ratio of the number of gallium arsenide monolayers to a sum of the number of gallium arsenide monolayers and the number of indium arsenide monolayers in the laminate. In this case, a lattice strain of the gallium arsenide antimonide layer can be reduced.

(3) In the above (1) or (2), j, m, and n may be each 6 or less.

(4) In any one of the above (1) to (3), k may be 1 or more.

(5) In any one of the above (1) to (4), k may be 13 or less.

(6) In any one of the above (1) to (5), the gallium arsenide antimonide layer may have an arsenic fraction of 0.3 to 0.7.

(7) In any one of the above (1) to (6), the gallium arsenide antimonide layer may include p gallium arsenide antimonide monolayers, and p may be an integer of 10 to 26.

(8) In any one of the above (1) to (7), the first gallium arsenide layer, the second gallium arsenide layer, and the third gallium arsenide layer each may have a thickness of 0.2 nm to 1.5 nm.

(9) In any one of the above (1) to (8), the first indium arsenide layer and the second indium arsenide layer each may have a thickness of 0.2 nm to 1.6 nm.

(10) In any one of the above (1) to (9), the gallium arsenide antimonide layer may have a thickness of 2.5 nm to 6.3 nm.

[Details of Embodiments of Present Disclosure]

Hereinafter, embodiments of the present disclosure will be described in detail with reference to the accompanying drawings. In the description of the drawings, the same reference numerals are used for the same or equivalent elements, and redundant description is omitted.

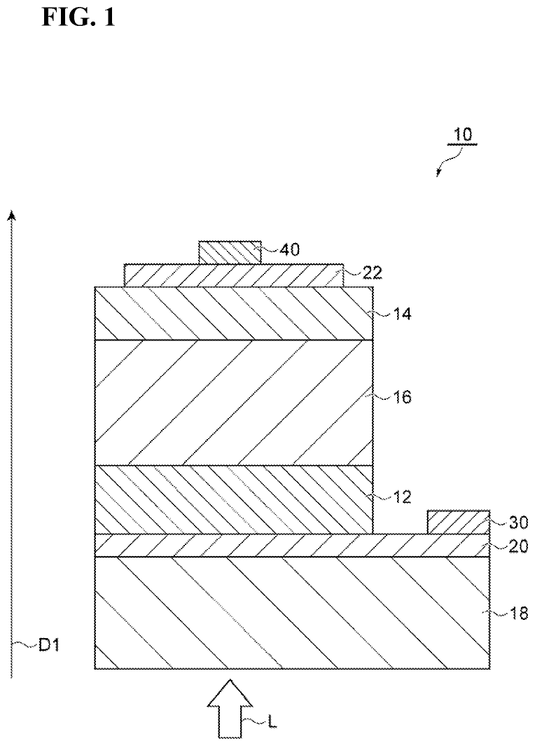

FIG. 1 schematically shows a cross-sectional view of a semiconductor photodetector according to an embodiment. A semiconductor photodetector 10 shown in FIG. 1 comprises a first group III-V semiconductor layer 12 of a first conductivity type, a second group III-V semiconductor layer 14 of a second conductivity type, and an optical absorption layer 16. The first conductivity type is, for example, n-type. The second conductivity type is opposite to the first conductivity type. The second conductivity type is, for example, p-type. Optical absorption layer 16 is undoped. Semiconductor photodetector 10 is a photodiode, for example. Optical absorption layer 16 is disposed between first group III-V semiconductor layer 12 and second group III-V semiconductor layer 14 in a first direction D1. First direction D1 is a thickness direction of optical absorption layer 16. First direction D1 may be a direction from first group III-V semiconductor layer 12 toward second group III-V semiconductor layer 14. First direction D1 may be a crystal growth direction. Alternatively, first direction D1 may be a direction from second group III-V semiconductor layer 14 toward first group III-V semiconductor layer 12. First direction D1 may be a direction opposite to the crystal growth direction.

First group III-V semiconductor layer 12 may be an indium phosphide (InP) layer. A dopant concentration in first group III-V semiconductor layer 12 may be 1×10²³ m⁻³ to 1×10²⁴ m⁻³. First group III-V semiconductor layer 12 may have a thickness of 0.1 μm to 1 μm. Examples of n-type dopants include silicon (Si), tellurium (Te), and tin (Sn).

Second group III-V semiconductor layer 14 may be an InP layer. A dopant concentration in second group III-V semiconductor layer 14 may be 1×10²³ m⁻³ to 1×10²⁴ m⁻³. Second group III-V semiconductor layer 14 may have a thickness of 0.1 μm to 1 μm. Examples of p-type dopants include zinc (Zn) and beryllium (Be).

Semiconductor photodetector 10 may further comprise a substrate 18. Substrate 18 may be a III-V semiconductor substrate such as an InP substrate. Substrate 18 may be a semi-insulating substrate. In first direction D1, first group III-V semiconductor layer 12 may be disposed between substrate 18 and optical absorption layer 16. First group III-V semiconductor layer 12 may be disposed on a main surface of substrate 18. The main surface of substrate 18 may be a {100} plane. The {100} plane includes a (100) plane, a (010) plane, a (001) plane, a (−100) plane, a (0-10) plane, and a (00-1) plane. The (100) plane, the (010) plane, the (001) plane, the (−100) plane, the (0-10) plane, and the (00-1) plane are equivalent to each other. The main surface of substrate 18 may be orthogonal to first direction D1.

Semiconductor photodetector 10 may further comprise a group III-V semiconductor layer 20 of the first conductivity type. Group III-V semiconductor layer 20 is disposed between first group III-V semiconductor layer 12 and substrate 18 in first direction D1. Group III-V semiconductor layer 20 may be a contact layer. Group III-V semiconductor layer 20 may be an InP layer. An electrode 30 may be connected to group III-V semiconductor layer 20.

Semiconductor photodetector 10 may further comprise a group III-V semiconductor layer 22 of the second conductivity type. In first direction D1, second group III-V semiconductor layer 14 is disposed between group III-V semiconductor layer 22 and optical absorption layer 16. Group III-V semiconductor layer 22 may be a contact layer. Group III-V semiconductor layer 22 may be a Ga_{z}In_{1-z}As layer (also referred to as a GaInAs layer). The z is a gallium (Ga) fraction. The z is more than 0 and less than 1. An electrode 40 may be connected to group III-V semiconductor layer 22.

Semiconductor photodetector 10 can detect an incident light L. Incident light L may be visible light or infrared light having a wavelength of 0.4 to 3 μm. Incident light L may travel in first direction D1. Incident light L may be incident on optical absorption layer 16 through substrate 18. Semiconductor photodetector 10 may be used in a spectroscopic system of a gas analyzer, an imaging system or an optical communication system.

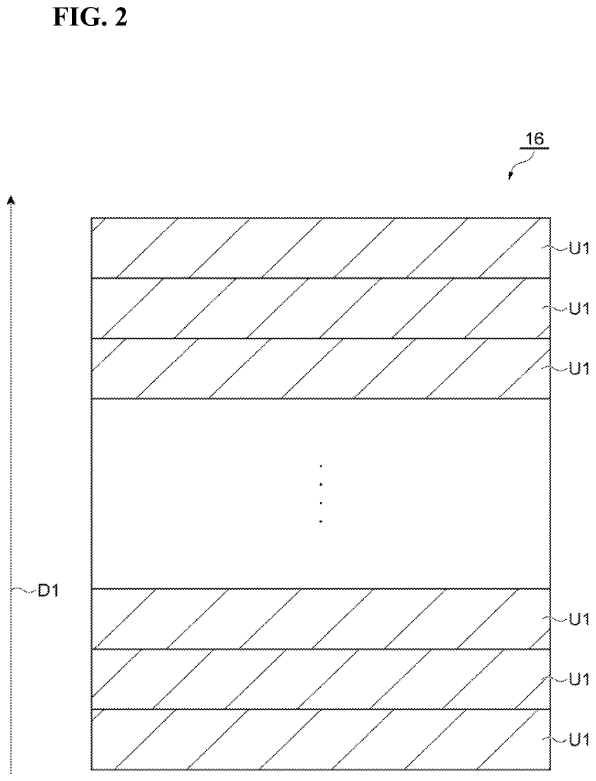

FIG. 2 is a cross-sectional view schematically showing an optical absorption layer included in the semiconductor photodetector of FIG. 1. As shown in FIG. 2, optical absorption layer 16 includes a plurality of unit structures U1 stacked in first direction D1. Adjacent unit structures U1 may be in contact with each other. The number of unit structures U1 may be 100 to 500. The plurality of unit structures U1 constitute a superlattice.

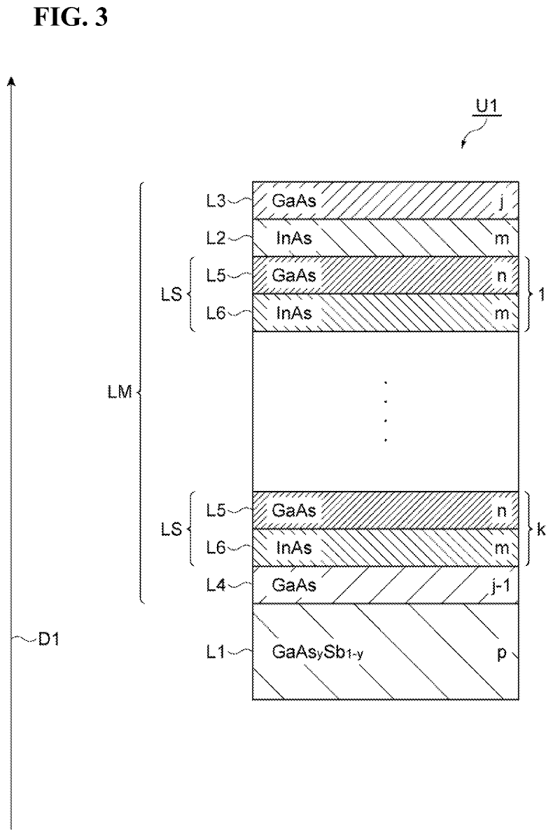

FIG. 3 is a cross-sectional view schematically showing a unit structure included in the optical absorption layer of FIG. 2. As shown in FIG. 3, each unit structure U1 includes a laminate LM and a gallium arsenide antimony (GaAs_{y}Sb_{1-y}) layer L1. GaAs_{y}Sb_{1-y} layer L1 and laminate LM may be stacked in this order in first direction D1. Alternatively, laminate LM and GaAs_{y}Sb_{1-y} layer L1 may be stacked in this order in first direction D1. They is an arsenic (As) fraction. The y is more than 0 and less than 1. The y may be 0.3 to 0.7. In this case, GaAs_{y}Sb_{1-y} layer L1 can be lattice-matched to the InP layer. GaAs_{y}Sb_{1-y} layer L1 may include p GaAs_{y}Sb_{1-y} monolayers. The p may be an integer of 10 to 26. A monolayer means a layer containing a single molecule (group III-V compound semiconductor molecule) in the thickness direction. In the case of a III-V compound semiconductor having a zincblende structure, the thickness of the monolayer is half the length of the lattice constant in the thickness direction. monolayer has a thickness of 0.28 nm to 0.32 nm, for example. The thickness of the monolayer may vary depending on the type of material, the temperature or the amount of lattice strain.

Laminate LM includes a gallium arsenide (GaAs) layer L3 (first gallium arsenide layer), an indium arsenide (InAs) layer L2 (first indium arsenide layer), k stacked structures LS, and a GaAs layer L4 (second gallium arsenide layer). GaAs layer L3 includes j GaAs monolayers. InAs layer L2 includes m InAs monolayers. GaAs layer L4 includes (j−1) GaAs monolayers. Each stacked structure LS includes a GaAs layer L5 (third gallium arsenide layer) and an InAs layer L6 (second indium arsenide layer). Each stacked structure LS may be a pair including single GaAs layer L5 and single InAs layer L6. GaAs layer L5 includes n GaAs monolayers. InAs layer L6 includes m InAs monolayers. GaAs layer L4, k stacked structures LS, InAs layer L2, and GaAs layer L3 are stacked in this order in first direction D1. In each stacked structure LS, InAs layer L6 and GaAs layer L5 are stacked in this order in first direction D1. In laminate LM, the GaAs layer and the InAs layer may be alternately stacked in first direction D1.

Each of j, m, and n is an integer of 1 or more. Each of j, m, and n may be each 6 or less. The j and the m may be the same integer or different from each other. The m and the n may be the same integer or different from each other. The n and the j may be the same integer or different from each other. When the j is 1, laminate LM does not include GaAs layer L4. The k is an integer of 0 or more. The k may be 1 or more. The k may be 13 or less. When the k is 0, laminate LM does not include stacked structure LS.

In unit structure U1, the arrangement of the GaAs monolayers, the InAs monolayers, and the GaAs_{y}Sb_{1-y} monolayers may be represented as follows. (GaAs)ⱼ(InAs)ₘ([GaAs]ₙ[InAs]ₘ)ₖ(GaAs)ⱼ₋₁(GaAs_{y}Sb_{1-y})ₚ

An arrangement order of the monolayers is an order in a direction opposite to first direction D1. Each of j, m, n, (j−1), and p at the bottom right of each monomolecular represents the number of monolayers as described above. The k represents the number of pairs represented by ([GaAs]n[InAs]m).

InAs layer L2 may be in contact with GaAs layer L3 and GaAs layer L5. InAs layer L6 may be in contact with GaAs layer L5. GaAs layer L4 may be in contact with InAs layer L6 and GaAs_{y}Sb_{1-y} layer L1. GaAs layer L3 in one unit structure U1 may be in contact with GaAs_{y}Sb_{1-y} layer L1 in adjacent unit structure U1. GaAs_{y}Sb_{1-y} layer L1 may function as an electron barrier layer or a hole well layer. Laminate LM may function as an electron well layer or a hole barrier layer.

Each of InAs layers L2 and L6 and GaAs layers L3, L4 and L5 has a smaller thickness than GaAs_{y}Sb_{1-y} layer L1. GaAs_{y}Sb_{1-y} layer L1 may have a thickness of 2.5 nm to 6.3 nm. InAs layers L2 and L6 may each have a thickness of 0.2 nm to 1.6 nm. GaAs layers L3, L4, and L5 may each have a thickness of 0.2 nm to 1.5 nm.

The following formula (1) may be satisfied, where y is the As fraction in GaAs_{y}Sb_{1-y} layer L1, and r is a ratio of the number of GaAs monolayers to a sum of the number of GaAs monolayers and the number of InAs monolayers in laminate LM.

0.95<y+r<1.05 (1)

When the number of GaAs monolayers in laminate LM is N1 and the number of InAs monolayers in laminate LM is N2, the r is expressed by the following formula (2).

r=N1/(N1+N2) (2)

N1 is expressed by the following formula (3).

N1=n×k+2j−1 (3)

N2 is expressed by the following formula (4).

N2=m×(k+1) (4)

The r may be more than 0.4 and less than 0.6. In this case, the y is more than 0.35 and less than 0.65. Thereby, a lattice strain c of GaAs_{y}Sb_{1-y} layer L1 in a lamination plane can be made more than −1.2% and less than 1.1%. As a result, good crystallinity can be obtained when GaAs_{y}Sb_{1-y} layer L1 has a thickness of about 10 nm or less.

According to semiconductor photodetector 10, laminate LM in each unit structure U1 functions as the electron well layer. In semiconductor photodetector 10, the spectrum of the optical-absorption coefficient has lower dependence on the polarization direction of incident light L than in the case where the electron well layer in each unit structure is formed only of the GaInAs layer. This is considered to be because the atomic arrangement has symmetry with respect to the center position of the electron well layer in first direction D1. According to semiconductor photodetector 10, even when the polarization direction of incident light L is changed, a change in signal intensity can be suppressed.

Various experiments conducted to evaluate unit structure U1 of FIG. 3 will be described below. The experiments described below are not intended to limit the present disclosure.

(First Experiment)

An optical absorption layer of a semiconductor photodetector according to a first experiment has the following configuration. Each unit structure in the optical absorption layer includes GaAs layer L3, InAs layer L2, GaAs layer L5, InAs layer L6, GaAs layer L4, and GaAs_{y}Sb_{1-y} layer L1 (see FIG. 3). The optical absorption layer is stacked above a {100} plane of an InP substrate.

The number j of GaAs monolayers in GaAs layer L3 is 2. The number m of InAs monolayers in InAs layer L2 is 2. The number n of GaAs monolayers in GaAs layer L5 is 2. The number m of InAs monolayers in InAs layer L6 is 2. The number k of stacked structures LS is 3. The number (j−1) of GaAs monolayers in GaAs layer L4 is 1. GaAs_{y}Sb_{1-y} layer L1 has an As fraction y of 0.49. The number p of GaAs_{y}Sb_{1-y} monolayers in GaAs_{y}Sb_{1-y} layer L1 is 17.

In each unit structure in the optical absorption layer, an arrangement of the GaAs monolayers, the InAs monolayers, and the GaAs_{y}Sb_{1-y} monolayers is also represented as follows. ([GaAs]₂[InAs]₂)₄(GaAs)(GaAs_{0.49}Sb_{0.51})₁₇

(Second Experiment)

An optical absorption layer of a semiconductor photodetector according to a second experiment has the following structure. Each unit structure in the optical absorption layer includes a GaAs_{y}Sb_{1-y} layer and a gallium indium arsenide (GaₓIn₁₋ₓAs) layer. The optical absorption layer is stacked on a {100} plane of an InP substrate. The y is 0.51. The x is 0.47. The number of GaxIn₁₋ₓAs monolayers in the GaxIn₁₋ₓAs layer is 17. The number of GaAs_{y}Sb_{1-y} monolayers in the GaAs_{y}Sb_{1-y} layer is 17.

(First Experimental Results)

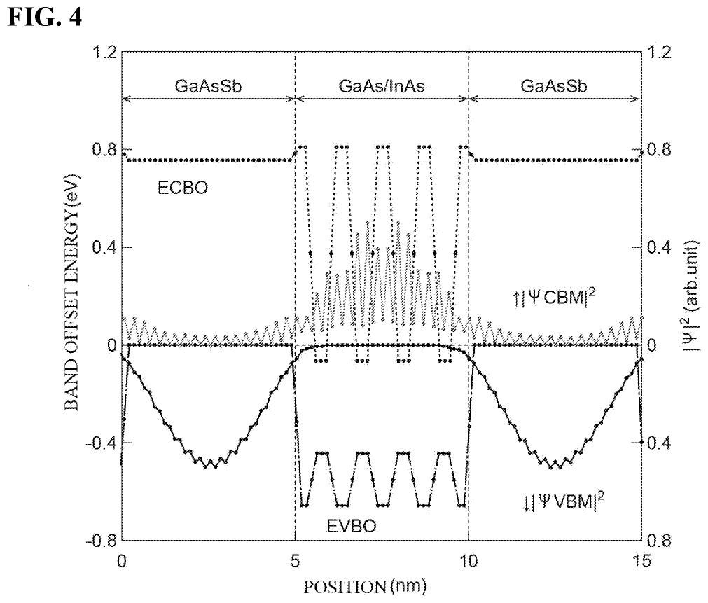

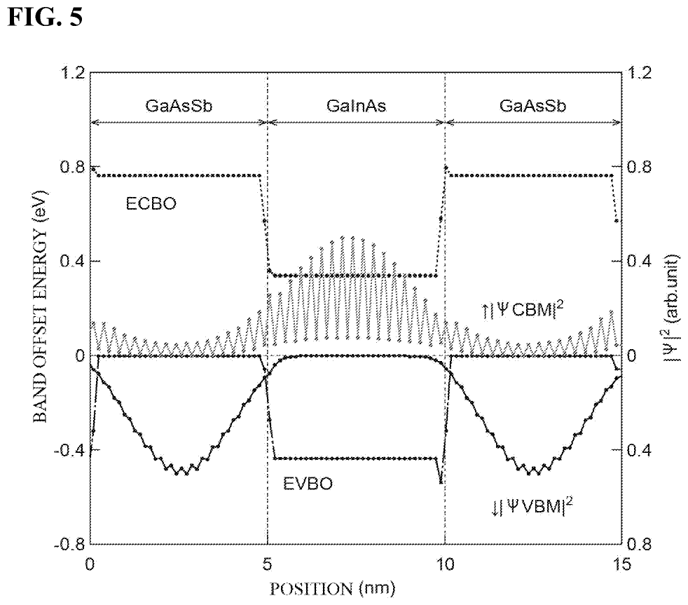

For the optical absorption layers of the semiconductor photodetectors according to the first experiment and the second experiment, band offset energies and squares of absolute values of magnitudes of wave functions were calculated by simulation. The results are shown in FIGS. 4 and 5.

FIGS. 4 and 5 are graphs showing examples of energy band diagrams in the optical absorption layers of the semiconductor photodetectors according to the first experiment and the second experiment, respectively. In each graph of FIGS. 4 and 5, the horizontal axis represents a position of each atom in first direction D1. The left vertical axis of the graph represents the band offset energy (eV). ECBO represents a band offset energy of a conduction band at F point where the wave number is 0 (also referred to as a conduction band edge). EVBO represents a band offset energy of a valence band at F point where the wave number is 0 (also referred to as a valence band edge). The right vertical axis of the graph represents the value (arbitrary unit) of the square of the absolute value of the magnitude of the wave function. |ψCBM|² represents the square of the absolute value of the magnitude of the wave function at the conduction band edge. |ψCBM|² is located above the value of 0 on the right vertical axis. |ψVBM|² represents the square of the absolute value of the magnitude of the wave function at the valence band edge. |ψVBM|² is located below the value of 0 on the right vertical axis.

As shown in FIGS. 4 and 5, the energy bands and the wave functions in the electron well layer are different between the first experiment and the second experiment.

(Second Experimental Results)

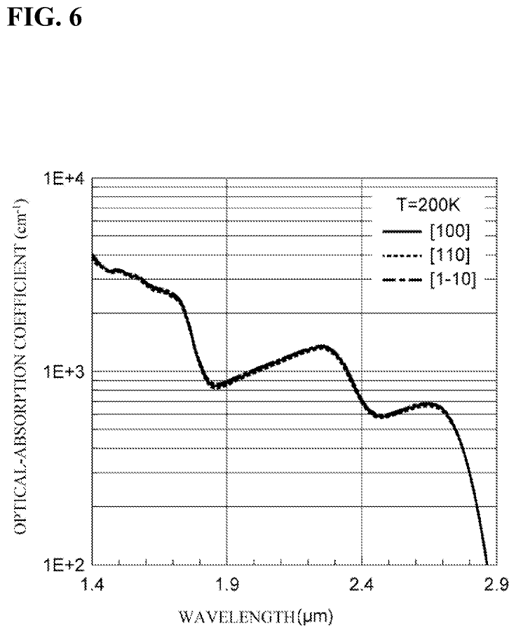

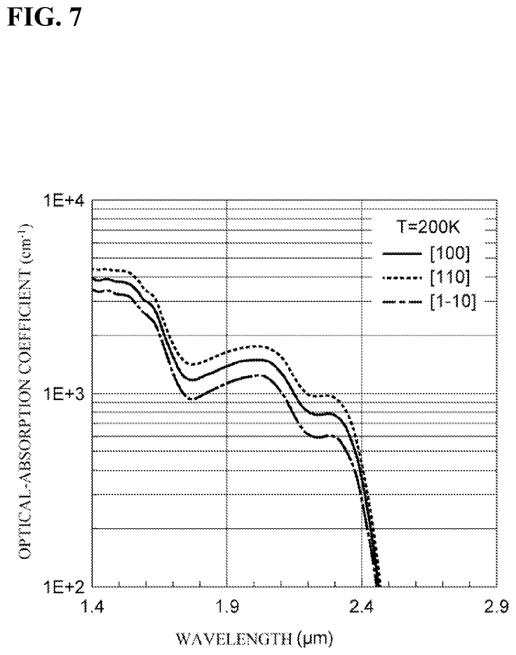

For the optical absorption layers of the semiconductor photodetectors according to the first experiment and the second experiment, spectra of optical-absorption coefficients at an operating temperature of 200 K were calculated by simulation. Incident light L travels in first direction D1 perpendicular to the (001) plane (see FIG. 1). The results are shown in FIGS. 6 and 7.

FIGS. 6 and 7 are graphs showing examples of spectra of optical-absorption coefficients obtained in the first experiment and the second experiment, respectively. In each graph of FIGS. 6 and 7, the vertical axis represents the optical-absorption coefficient (cm⁻¹). The horizontal axis represents a wavelength (μm). A solid line indicates the spectrum when the polarization direction of incident light L is the direction. A dashed line indicates the spectrum when the polarization direction of incident light L is the direction. A one dot chain line indicates the spectrum when the polarization direction of incident light L is the [1-10] direction.

As shown in FIG. 6, in the first experiment, even when the polarization direction of incident light L was changed, the spectrum of the optical-absorption coefficient was hardly changed. On the other hand, as shown in FIG. 7, in the second experiment, when the polarization direction of incident light L was changed, the spectrum of the optical-absorption coefficient was also largely changed. Accordingly, it can be seen that the spectrum of the optical-absorption coefficient in the first experiment has lower dependence on the polarization direction of incident light than that in the second experiment. Hereinafter, a mechanism in which dependency on the polarization direction is reduced will be described.

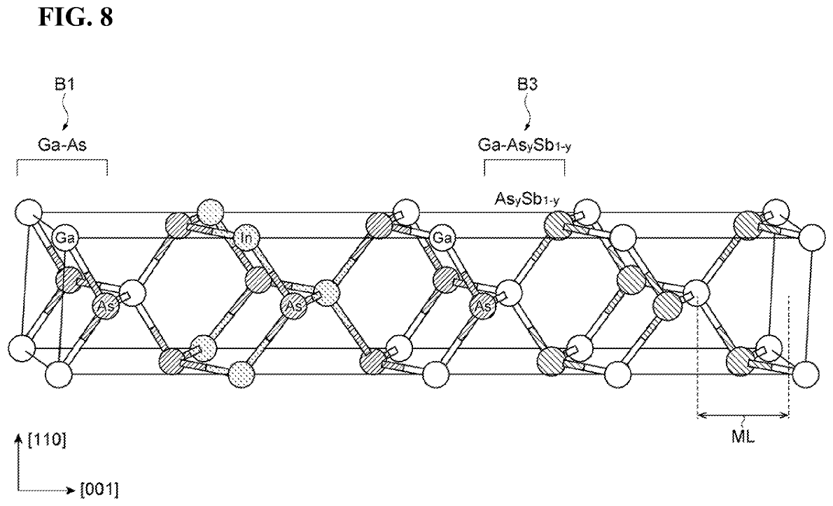

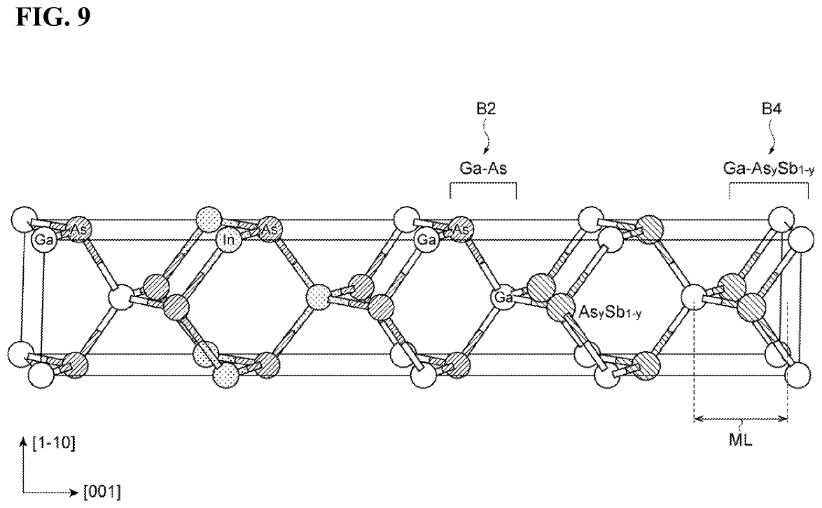

FIGS. 8 and 9 are perspective views showing an example of the atomic arrangement in the unit structure of the first experiment. In FIGS. 8 and 9, the direction is the crystal growth direction, i.e., first direction D1 in FIG. 3. In FIG. 8, an upward direction is the direction. On the other hand, in FIG. 9, the upward direction is the [1-10] direction. In FIGS. 8 and 9, ML represents a monolayer. In an atomic site designated as As_{y}Sb_{1-y}, either one of arsenic (As) atom and antimony (Sb) atom is actually arranged. In the plane perpendicular to the crystal growth direction, As atoms and Sb atoms are arranged at a ratio of y:(1−y) in terms of the number of atoms. Therefore, it can be considered that a virtual cation atom (As_{y}Sb_{1-y}) having a property of the ratio is arranged at the atomic site As_{y}Sb_{1-y}.

In FIG. 8, the number of interatomic bonds having a component in the direction was calculated. The numbers of Ga—As bonds, In—As bonds, and Ga—(As_{y}Sb_{1-y}) bonds are as follows:

Ga—As bond: 6(4×½+2+4×½)

In—As bond: 4(4×½+2)

Ga—(As_{y}Sb_{1-y}) bond: 6(2+4×½+2)

Since the interatomic bonds located on a surface of a cell indicated by a rectangular parallelepiped are shared with the adjacent cell, the number of interatomic bonds is halved.

In FIG. 9, the number of interatomic bonds having a component in the [1-10] direction was calculated. The numbers of Ga—As bonds, In—As bonds and Ga—(As_{y}Sb_{1-y}) bonds are as follows:

Ga—As bond: 6(2+4×½+2)

In—As bond: 4(4×½+2)

Ga—(As_{y}Sb_{1-y}) bond: 6(4×½+2+4×½)

Thus, in the first experiment, the number of interatomic bonds having a component in the same direction with respect to the electric field having the polarization direction in the direction is the same as the number of interatomic bonds having a component in the same direction with respect to the electric field having the polarization direction in the [1-10] direction. Further, as shown in FIG. 4, the electron well layer is arranged between a first electron barrier layer and a second electron barrier layer. An energy at an interface between the first electron barrier layer and the electron well layer is the same as an energy at an interface between the second electron barrier layer and the electron well layer. This is because the atomic arrangement has symmetry with respect to the center position of the electron well layer in first direction D1. Thus, a Ga—As bond B1 shown in FIG. 8 is equivalent to a Ga—As bond B2 shown in FIG. 9. Similarly, a Ga—(As_{y}Sb_{1-y}) bond B3 shown in FIG. 8 is equivalent to a Ga—(As_{y}Sb_{1-y}) bond B4 shown in FIG. 9. Therefore, the optical-absorption coefficient when the polarization direction is the direction is almost the same as the optical-absorption coefficient when the polarization direction is the [1-10] direction. In the first experiment, the spectrum of the optical-absorption coefficient has low dependence on the polarization direction of incident light.

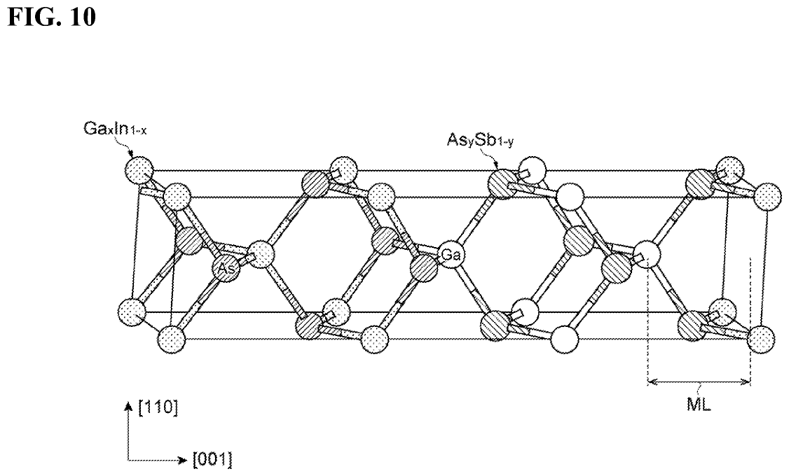

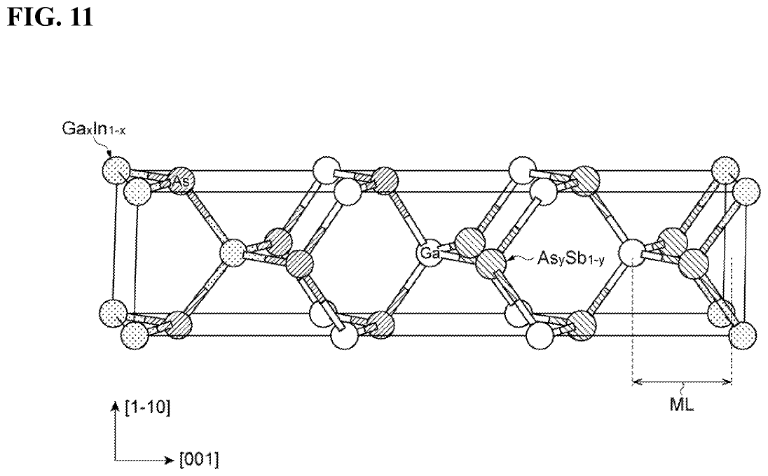

FIG. 10 and FIG. 11 are perspective views showing examples of atomic arrangements in the unit structure of the second experiment. In an atomic site designated as GaₓIn₁₋ₓ, a gallium (Ga) atom or an indium (In) atom is actually arranged. In a plane perpendicular to the crystal growth direction, the Ga atoms and the In atoms are arranged at a ratio of x:(1−x) in terms of the number of atoms. Therefore, it can be considered that a virtual cation atom (GaₓIn₁₋ₓ) having a property of the ratio is arranged at the atomic site GaₓIn₁₋ₓ.

In FIG. 10, the number of interatomic bonds having a component in the direction was calculated. The numbers of (GaₓIn₁₋ₓ)—As bonds, Ga—(As_{y}Sb_{1-y}) bonds, Ga—As bonds, and (GaₓIn₁₋ₓ)—(As_{y}Sb_{1-y}) bonds are as follows:

(GaxIn₁₋ₓ)—As bond: 6(4×½+2+4×½)

Ga—(As_{y}Sb_{1-y}) bond: 6(2+4×½+2)

Ga—As bond: 0

(GaxIn₁₋ₓ)—(As_{y}Sb_{1-y}) bond: 0

In FIG. 11, the number of interatomic bonds having a component in the [1-10] direction was calculated. The numbers of (GaxIn₁₋ₓ)—As bonds, Ga—(As_{y}Sb_{1-y}) bonds, Ga—As bonds, and (GaₓIn₁₋ₓ)—(As_{y}Sb_{1-y}) bonds are as follows:

(GaxIn₁₋ₓ)—As bond: 4(2+4×½)

Ga—(As_{y}Sb_{1-y}) bond: 4(4×½+2)

Ga—As bond: 2

(GaxIn₁₋ₓ)—(As_{y}Sb_{1-y}) bond: 2(4×½)

Thus, in the second experiment, the number of interatomic bonds having a component in the same direction with respect to an electric field having a polarization direction in the direction is different from the number of interatomic bonds having a component in the same direction with respect to an electric field having a polarization direction in the [1-10] direction. Therefore, the optical-absorption coefficient when the polarization direction is the direction is different from the optical-absorption coefficient when the polarization direction is the [1-10] direction. In the second experiment, the spectrum of the optical-absorption coefficient has high dependence on the polarization direction of incident light.

(Third Experiment to 25th Experiment)

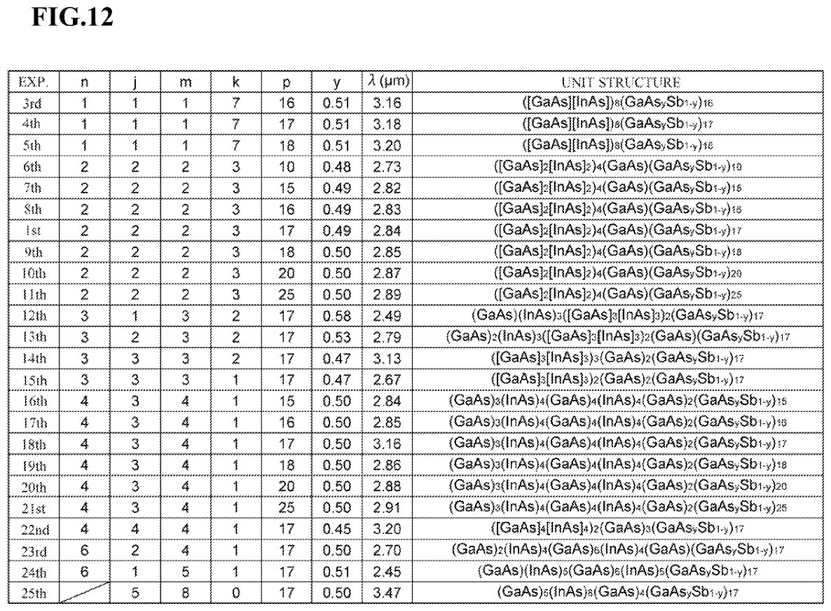

The unit structures included in the optical absorption layer of the semiconductor photodetectors according to the third to 25th second experiments are shown in FIG. 12.

(Third Experimental Result)

For the optical absorption layers of the semiconductor photodetectors according to the first experiment and the third to 25th experiments, wavelengths of the optical absorption edge λ (μm) at the operating temperature of 200 K were calculated by simulation. Here, the wavelengths of the optical absorption edge (cutoff wavelengths) are the maximum values of the wavelengths at which the optical-absorption coefficient is 1×10² cm⁻¹ or more. The results are shown in FIG. 12.

FIG. 12 is shows examples of wavelengths of the optical absorption edge in unit structures of the first experiment, the third experiment to the 25th experiment. As shown in FIG. 12, the wavelength of the optical absorption edge was 2.45 μm or more in the first experiment, and in the third experiment to the 25th experiment. In the third to the 25th experiments, the spectra of the optical-absorption coefficients have low dependence on the polarization direction of the incident light as in the first experiment.

Although preferred embodiments of the present disclosure have been described in detail above, the present disclosure is not limited to the above embodiments.

It should be understood that the embodiments disclosed herein are illustrative in all respects and are not restrictive. The scope of the present invention is defined by the appended claims rather than by the foregoing description, and is intended to include all modifications within the scope and meaning equivalent to the appended claims.

What is claimed is:

1. A semiconductor photodetector comprising:
a first group III-V semiconductor layer of a first conductivity type;
a second group III-V semiconductor layer of a second conductivity type; and
an optical absorption layer disposed between the first group III-V semiconductor layer and the second group III-V semiconductor layer in a first direction,
wherein the optical absorption layer includes a plurality of unit structures stacked in the first direction,
each of the plurality of unit structures includes a laminate and a gallium arsenide antimonide layer,
the laminate includes a first gallium arsenide layer including j gallium arsenide monolayers, a first indium arsenide layer including m indium arsenide monolayers, k stacked structures, and a second gallium arsenide layer including (j−1) gallium arsenide monolayers, the second gallium arsenide layer, the k stacked structures, the first indium arsenide layer, and the first gallium arsenide layer are stacked in this order in the first direction, each of the k stacked structures includes a third gallium arsenide layer including n gallium arsenide monolayers and a second indium arsenide layer including m indium arsenide monolayers, and in each of the k stacked structures, the second indium arsenide layer and the third gallium arsenide layer are stacked in this order in the first direction, and
j, m, and n are each an integer of 1 or more, and k is an integer of 0 or more.

2. The semiconductor photodetector according to claim 1, further comprising an indium phosphide substrate,
wherein the first group III-V semiconductor layer is disposed between the indium phosphide substrate and the optical absorption layer in the first direction, and
0.95<y+r<1.05 is satisfied, where y is an arsenic fraction in the gallium arsenide antimonide layer, and r is a ratio of the number of gallium arsenide monolayers to a sum of the number of gallium arsenide monolayers and the number of indium arsenide monolayers in the laminate.

3. The semiconductor photodetector according to claim 1, wherein j, m, and n are each 6 or less.

4. The semiconductor photodetector according to claim 1, wherein k is 1 or more.

5. The semiconductor photodetector according to claim 1, wherein k is 13 or less.

6. The semiconductor photodetector according to claim 1, wherein the gallium arsenide antimonide layer has an arsenic fraction of 0.3 to 0.7.

7. The semiconductor photodetector according to claim 1, wherein the gallium arsenide antimonide layer includes p gallium arsenide antimonide monolayers, and
p is an integer of 10 to 26.

8. The semiconductor photodetector according to claim 1, wherein the first gallium arsenide layer, the second gallium arsenide layer, and the third gallium arsenide layer each have a thickness of 0.2 nm to 1.5 nm.

9. The semiconductor photodetector according to claim 1, wherein the first indium arsenide layer and the second indium arsenide layer each have a thickness of 0.2 nm to 1.6 nm.

10. The semiconductor photodetector according to claim 1, wherein the gallium arsenide antimonide layer has a thickness of 2.5 nm to 6.3 nm.
